(19) United States
(12) Patent Application Publication
(10) Pub. No.: US 2015/0108431 A1
(43) Pub. Date: Apr. 23, 2015

(54) MULTILAYER TRANSITION METAL DICHALCOGENIDE DEVICE, AND SEMICONDUCTOR DEVICE USING SAME

(71) Applicant: UNIVERSITY-INDUSTRY COOPERATION GROUP OF KYUNG HEE UNIVERSITY, Yongin-si (KR)

(72) Inventor: Sun Kook Kim, Yongin-si (KR)

(73) Assignee: UNIVERSITY-INDUSTRY COOPERATION GROUP OF KYUNG HEE UNIVERSITY, Yongin-si (KR)

(21) Appl. No.: 14/403,081

(22) PCT Filed: Mar. 20, 2013
(86) PCT No.: PCT/KR2013/002283

§ 371 Date: Nov. 21, 2014

(30) Foreign Application Priority Data
May 23, 2012 (KR) 10-2012-0054568

(51) Int. Cl. H01L 31/032; H01L 29/78

(52) U.S. Cl. CPC H01L 31/0324; H01L 29/78
USPC 257/21

(57) ABSTRACT

The present invention relates to a multilayer transition metal dichalcogenide device and a semiconductor device using the same, wherein the invention, preferably comprising three or more layers, is formed with a conventional single-layered transition metal chalcogenide, thereby enabling absorption of the light over a wide wavelength range from ultraviolet rays to near infrared rays. To this end, disclosed is a transition metal dichalcogenide formed to allow absorption of the light over a relatively wider wavelength range compared with a single-layered transition metal chalcogenide, and a transition metal dichalcogenide device having a semiconductor channel formed by a transition metal dichalcogenide.

### TECHNICAL FIELD

The present invention relates to a multilayered transition metal dichalcogenide device and a semiconductor device using the same, and more particularly, to the invention for configuring conventional single-layered transition metal dichalcogenides as multiple layers including three or more layers to absorb a light in a relatively wide wavelength range from ultraviolet rays to near-infrared rays.

### RELATED ART

Any of transition metal dichalcogenides is provided in a common crystalline structure and refers to various types of peculiar physical properties having electrically, magnetically, and optically great anisotropy at the same time. In the related art, there has been an interest on the explanation and application of the physical properties.

A single-layer MoS₂ phototransistor using such transition metal dichalcogenides shows a characteristic of a direct transition band-gap of 1.8 eV and thus, has an issue in that it is possible to absorb a light of a wavelength less than 700 nm. Also, when forming the transistor as a single layer, a growth and a deposition were difficult due to a thickness of about 1 nm.

ACS NANO publications regarding single-layer MoS₂ phototransistors published on Dec. 13, 2011 disclosed a characteristic of a material having a direct transition band-gap of 1.8 eV. It can be known that a single-layer MoS2 phototransistor is capable of absorbing a light in a wavelength range less than 700 nm by the direct transition band-gap.

### DETAILED DESCRIPTION OF THE INVENTION

### Technical Subjects

The present invention is conceived to solve the aforementioned issues and thus, provides the invention capable of generating two-dimensional (2D) transition metal dichalcogenides as multiple layers and thereby absorbing a light in a wide wavelength range by an indirect transition band-gap.

However, objects of the present invention are not limited thereto and other objects not described herein may be clearly understood by those skilled in the art from the following description.

### Solutions

The foregoing objects may be achieved by providing a multilayered transition metal dichalcogenide device wherein multilayered transition metal dichalcogenides are formed to absorb a light in a relatively wide wavelength range compared to single-layered transition metal dichalcogenides, and a semiconductor channel is formed by the multilayered transition metal dichalcogenides.

Also, due to a relatively small energy of a semiconductor band-gap compared to the single-layered transition metal dichalcogenides, the multilayered transition metal dichalcogenides may absorb the light in the relatively wide wavelength range.

Also, the single-layered transition metal dichalcogenides may absorb the light by a direct transition band-gap, and the multilayered transition metal dichalcogenides may absorb the light by an indirect transition band-gap.

Also, the multilayered transition metal dichalcogenides may be compounds of at least one of MoS₂, MoSe₂, WSe₂, MoTe₂, and SnSe₂.

Also, the multilayered transition metal dichalcogenides are capable of absorbing the light corresponding to a wavelength of an area ranging from ultraviolet rays to near-infrared rays.

Meanwhile, the objects of the present invention may be achieved by providing a semiconductor device operating in response to a wavelength of light incident by the multilayered transition metal dichalcogenide device.

### EFFECTS OF THE INVENTION

As described above, according to embodiments of the present invention, it is possible to absorb a light in a relatively wide wavelength range compared to single-layered transition metal dichalcogenides.

Also, according to embodiments of the present invention, it is possible to detect a wavelength ranging from ultraviolet rays to near-infrared rays.

Also, according to embodiments, compared to InGaZnO compound, it is possible to achieve a high mobility and to decrease a gate operation bias voltage. In addition, a shift of a threshold voltage does not occur when emitting a light.

### BRIEF DESCRIPTION OF DRAWINGS

FIG. 1 illustrates a three-dimensional (3D) structure of single-layered MoS₂.

FIGS. 2 and 3 are 3D views of a single-layered MoS₂ transistor.

FIG. 4 is a graph showing an absorption spectrum of MoS₂ crystals having different thicknesses.

FIG. 5 illustrates a band structure of bulk MoS₂.

FIG. 6 is a graph showing E-k of a direct transition band-gap.

FIG. 7 is a graph showing E-k of an indirect transition band-gap.

FIG. 8 is a graph showing Id-Vgs characteristic curves of a MoS₂ phototransistor.

### EXPLANATION OF SYMBOLS ABOUT PRIMARY PORTION OF DRAWINGS

1: Single-layered MoS₂ transistor

### BEST MODE FOR CARRYING OUT THE INVENTION

Hereinafter, exemplary embodiments of the present invention will be described with reference to the accompanying drawings. Also, embodiments to be described in the following do not unfairly limit the description of the invention disclosed in the claims and the entire configuration described in the embodiments cannot be understood to be essential to carry out the invention.

### <Configuration of a Multilayered Transition Metal Dichalcogenide Device>

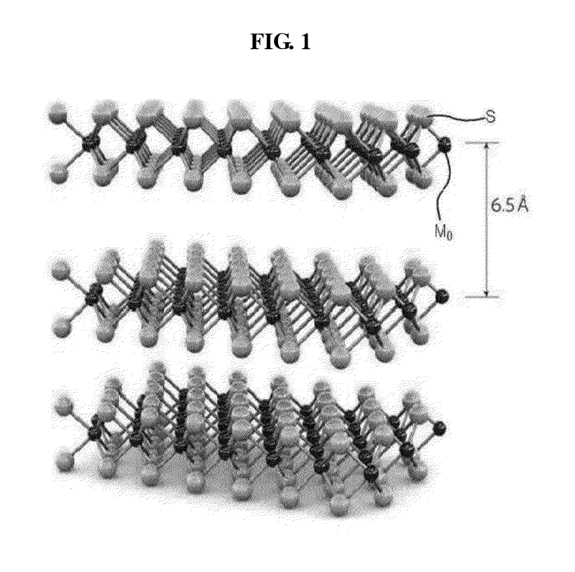

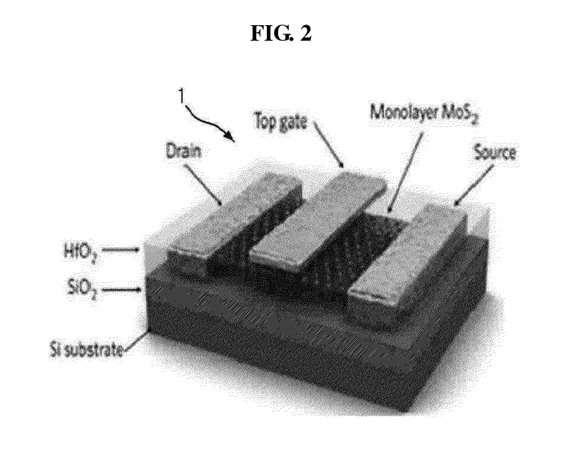

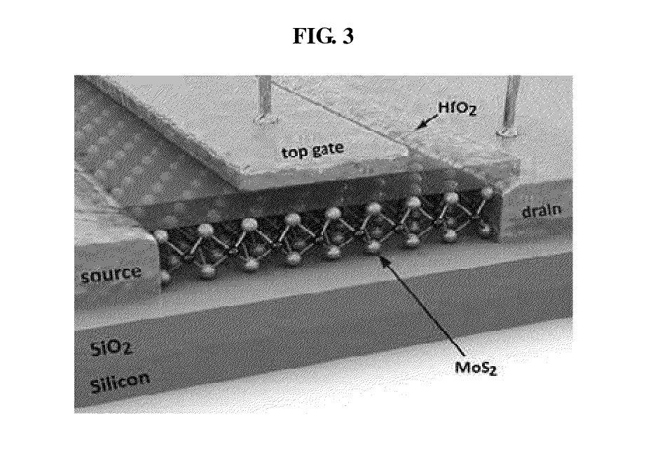

Compared to one-dimensional (1D) materials, it is relatively easy to produce a complex structure with two-dimensional (2D) materials and thus, it is appropriate to use a 2D material as a material of a next-generation nano-electronic device. Among such 2D materials, 2D transition metal dichalcogenides include compounds of MoS₂, MoSe₂, WSe₂, MoTe₂, or SnSe₂. Here, a structure of single-layered MOS₂ is illustrated in FIG. 1. As illustrated in FIG. 1, single-layered MoS₂ crystals are vertically stacked and form a layer based on a van der Waals attraction with a thickness of a single layer as about 6.5 Å.

Although the single-layered MoS₂ has a unique band-gap of 1.8 eV, the mobility thereof is about 0.5 to 3 cm²V⁻¹s⁻¹ corresponding to a significantly low level. In addition, compared to a mobility value of graphene or thin-film silicon, the mobility may decrease according to an increase in the band-gap. To overcome such disadvantages, halfnium oxide (HfO₂) having a relatively high dielectric constant of about 25 was used for an upper gate and single-layered MoS₂ having the mobility of 200 cm²V⁻¹s⁻¹ or more was used as a booster below the upper gate. The above process may not match a thin film transistor (TFT) process employed in the related art.

On the contrary, according to embodiments of the present invention, multilayered transition metal dichalcogenides may be used as a channel instead of using halfnium oxide for the upper gate, which is employed in the single layer. Thus, the mobility has been enhanced to be 50 cm²V⁻¹s⁻¹ through an increase in conductivity resulting from multiple layers. By enhancing the mobility through the aforementioned single process, a process matching the conventional TFT technology is achieved.

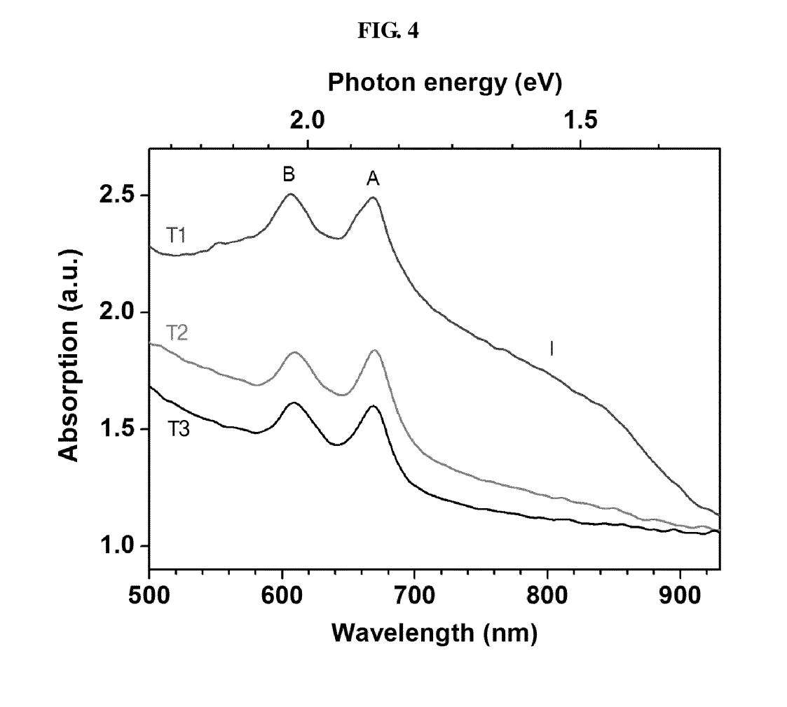

The aforementioned single-layered MoS₂ may absorb a light of a wavelength less than about 700 nm as shown in T2 and T3 of the graph of FIGS. 4. T1, T2, and T3 denote thicknesses of MoS₂ crystals, respectively. The thicknesses are in order of T1>T2>T3. T1 is about 40 nm, T2 is about 4 nm, and T3 is about 1 nm.

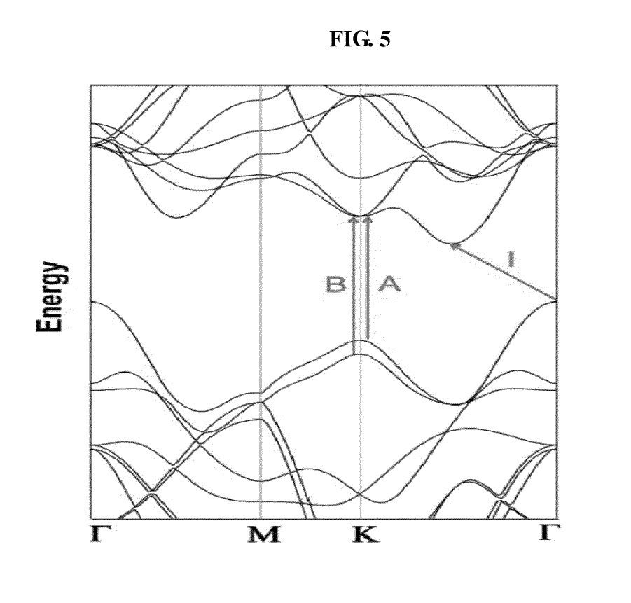

Referring to FIGS. 4 and 5, highest absorption points “A” and “B” correspond to a direct transition band-gap energy-separated from a valence band spin-orbit coupling. A tail “I” corresponds to an indirect transition band-gap.

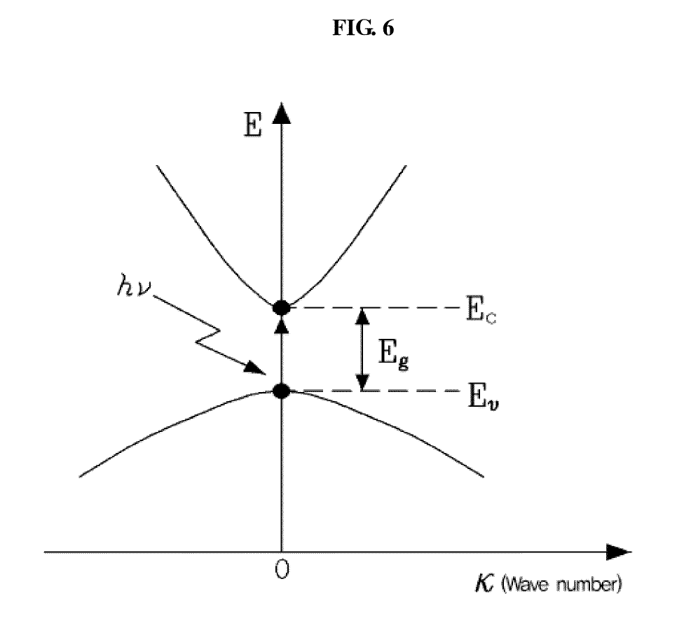

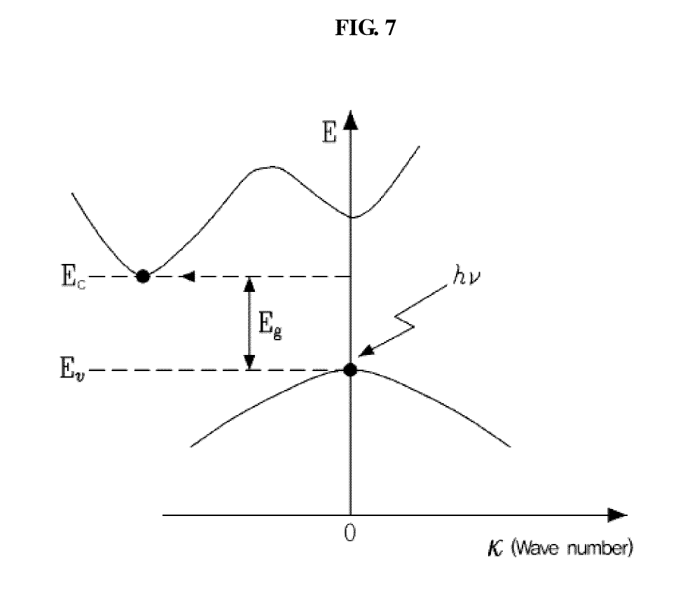

Meanwhile, referring to FIG. 6, a direct transition band-gap corresponds to a case in which energy Eᵥ(k)of a valence band occurs at the same wave number as energy E_{c}(k) of a conduction band. Referring to FIG. 7, an indirect transition band-gap corresponds to a case in which the two energies Eᵥ(k)and E_{c}(k) occur at different wave numbers. In the direct transition band-gap, a valence electron may make a direct transition to a conduction band due to light radiation energy hv. However, in the indirect transition band-gap, a valence electron may make an indirect transition to a conduction band, which leads to generating a phonon of energy Eₚₕ.

Accordingly, hv=E_{g} in the direct transition band-gap, and hv=E_{g}+Eₚₕ in the indirect transition band-gap. As described above, since Eₚₕ occurs in the indirect transition band-gap, an energy gap in the direct transition band-gap decreases from 1.8 eV (single-layered MoS₂) to 1.35 eV (multilayered MoS₂). Here, multiple layers may include, desirably, three or more layers.

When the energy gap decreases from 1.8 eV to 1.35 eV, a wavelength may vary according to the following Equation 1:

$$λ = \frac{1.24}{{E}_{g}} \qquad [ Equation 1 ]$$

When the energy gap is 1.35 eV rather than 1.8 eV, that is, when the energy gap is a small band-gap, a wavelength (λ) value increases. When multilayered MoS₂ is used compared to a case in which single-layered MoS₂ is used, it can be known from T1, T2, and T3 of FIG. 4 that it is possible to absorb a light of a wavelength over a wider range.

The single-layered MoS₂ may absorb a light of a wavelength less than 700 nm. However, the multilayered MoS₂, desirably, three or more layered MoS₂ according to embodiments of the present invention may absorb a light corresponding to all the wavelengths less than 1000 nm It indicates that it is possible to detect the wavelength range from near field infrared rays to ultraviolet rays.

The aforementioned multilayered transition metal dichalcogenides may be deposited in multiple layers using a general deposition method such as chemical vapor deposition (CVD), PE-CVD, atomic layer deposition (ALD), or sputter. Accordingly, a large scale growth may be relatively easily achieved compared to a single layer.

### <Configuration of a Semiconductor Device>

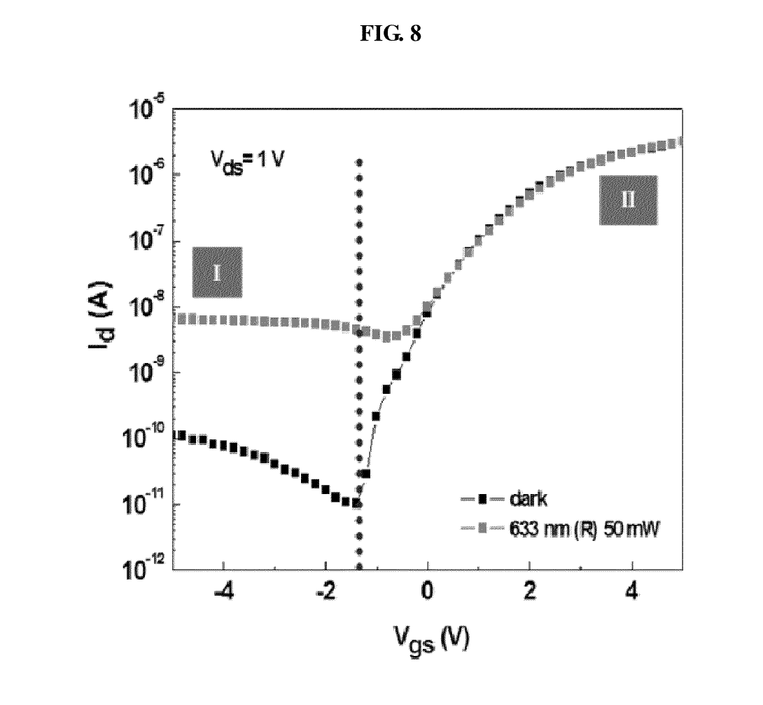

Referring to FIG. 8, it can be seen that a multilayered MoS₂ phototransistor shows an I_{d} difference of about 10³ with respect to a case in which a light is not incident and a case in which a light is incident (50 mWcm⁻² intensity of 633 nm).

Accordingly, a semiconductor device operating in reaction to a light may be configured by using the aforementioned multilayered transition metal dichalcogenides as a channel material. For example, a phototransistor device using a solar cell, a photo-detector, an optoelectronic device, a TFT structure, or a hybrid device (for example, P-type organic and N-type multilayered transition metal dichalcogenides).

Although embodiments of the present invention are described, the present invention is not limited thereto and various modification and applications can be made. That is, it will be understood by those skilled in the art that many alternations and changes can be made without departing from the scope of the invention.

### INDUSTRIAL APPLICABILITY

The present invention may absorb a light in a relatively wide wavelength range compared to single-layered transition metal dichalcogenides and may also detect a light with a wavelength ranging from ultraviolet rays to near-infrared rays. Also, compared to InGaZnO compound, it is possible to achieve a high mobility and to decrease a gate operation bias voltage. In addition, a shift of a threshold voltage does not occur when emitting a light.

What is claimed is:

1. A multilayered transition metal dichalcogenide device, wherein multilayered transition metal dichalcogenides are formed to absorb a light in a relatively wide wavelength range compared to single-layered transition metal dichalcogenides, and
a semiconductor channel is formed by the multilayered transition metal dichalcogenides.

2. The multilayered transition metal dichalcogenide device of claim 1, wherein, due to a relatively small energy-bandgap of a semiconductor band-gap compared to the single-layered transition metal dichalcogenides, the multilayered transition metal dichalcogenides absorb the light in the relatively wide wavelength range.

3. The multilayered transition metal dichalcogenides of claim 1, wherein the single-layered transition metal dichalcogenides absorb the light by a direct transition band-gap, and
the multilayered transition metal dichalcogenides absorb the light by an indirect transition band-gap.

4. The multilayered transition metal dichalcogenide device of claim 1, wherein the multilayered transition metal dichalcogenides are compounds of at least one of MoS₂, MoSe₂, WSe₂, MoTe₂, and SnSe₂.

5. The multilayered transition metal dichalcogenide device of claim 1, wherein the multilayered transition metal dichalcogenides are capable of absorbing the light corresponding to a wavelength of an area ranging from ultraviolet rays to near-infrared rays.

6. A semiconductor device operating in response to a wavelength of light incident by the multilayered transition metal dichalcogenide device of claim 1.
